(19) United States
(12) Patent Application Publication
(10) Pub. No.: US 2011/0268871 A1
(43) Pub. Date: Nov. 3, 2011

(54) SCREEN-PRINTING METHOD AND METHOD FOR MANUFACTURING THIN-FILM SOLAR CELL

(75) Inventor: Chieh-Hsien Chan, Tainan City (TW)

(73) Assignee: AURIA SOLAR CO., LTD., Tainan City (TW)

(21) Appl. No.: 13/180,867

(22) Filed: Jul. 12, 2011

(30) Foreign Application Priority Data
Apr. 29, 2011 (TW) 100115261

(51) Int. Cl. B05D 5/12

(52) U.S. Cl. 427/75

(57) ABSTRACT

A screen-printing method for forming a screen-printing layer on an object includes following steps. A screen is disposed on the object and ink is applied on the screen. The screen comprises a screen frame, a screen cloth, and an emulsion layer. Each warp and each weft of the screen are respectively parallel with or perpendicular to the screen frame. Each warp is perpendicular to each weft. The emulsion layer having a screen-printing pattern is disposed on the screen. A flood bar is moved along a first direction for covering the screen cloth with the ink. The ink is pressed downward by a scraper and the scraper is moved along a second direction for transferring part of the ink on the object through the screen-printing pattern, wherein a first angle between the scraper and the warps is in a range of 15° to 20° while the scraper is moved.

### CROSS-REFERENCE TO RELATED APPLICATIONS

This non-provisional application claims priority under 35 U.S.C. § 119(a) on Patent Application No(s). 100115261 filed in Taiwan, R.O.C. on Apr. 29, 2011, the entire contents of which are hereby incorporated by reference.

### BACKGROUND

1. Technical Field

The disclosure relates to a screen-printing method, and more particularly to a screen-printing method for manufacturing a thin-film solar cell.

2. Related Art

Screen-printing has been researched and wildly utilized since the technology can be applied in many technical fields. Among other things, the screen used in screen-printing is key to achieve good screen-printing quality.

FIGS. 1A and 1B are top and bottom views of a screen 100 used in screen-printing, respectively. The screen 100 includes an emulsion layer 102, a screen cloth 104, and a screen frame 106. The screen cloth 104 is obliquely arranged on the screen frame 106, so as to increase the strength and the service life of the screen cloth 104. One surface of the screen cloth 104 is arranged on the screen frame 106 with an oblique angle of 15°. The emulsion layer 102 having a screen-printing pattern, i.e. an opening area 50, is disposed on the other surface of the screen cloth 104.

In screen-printing, with the screen 100, a screen-printing layer 80 corresponding to the contour of the opening area 50 is formed on an object 90. However, inventors find that the shape of the screen-printing layer 80 is usually not the same as the contour of the opening area 50. That is to say, in theory, the shape of the screen-printing layer 80 should be the same as that illustrated in FIG. 2A which is a top view of the ideal screen-printing layer generated by the screen 100. But, referring to FIG. 2B, in practice, undesired serrated edges usually occur on the screen-printing layer 80 since the screen cloth 104 is obliquely arranged on the screen frame 106, and makes the shape of the screen-printing layer 80 not coincide with the contour of the opening area 50.

However, when the screen 100 is used to manufacture a high-precision product (for example, but not limited to, a solar cell), the serrated edges of the transfer-printing pattern would reduce the reliability of the product and deform the appearance of the product.

### SUMMARY

Accordingly, the disclosure relates to a screen-printing method and a method for manufacturing a thin-film solar cell, so as to solve the problem that serrated edges occur on the product formed by screen-printing.

One embodiment of the disclosure is a screen-printing method for forming a screen-printing layer on an object. The method comprises disposing the object below a screen. The screen comprises a screen frame, a screen cloth, and an emulsion layer. The screen cloth is knitted by warps and wefts and is arranged on the screen frame. Each of the warps and each of the wefts are respectively parallel with or perpendicular to the screen frame and each of the warps is perpendicular to each of the wefts. The emulsion layer is disposed on the screen cloth and has a screen-printing pattern. The steps of the method further comprise applying ink on the screen. A flood bar is moved along a first direction for covering the screen cloth with the ink. The ink is pressed downward by a scraper and the scraper is moved along a second direction for transferring at least a portion of the ink onto the object through the screen-printing pattern, wherein a first angle between the scraper and the wefts is in a range of 15° to 20° while the scraper is moved along the second direction.

Another embodiment of the disclosure is a method for manufacturing the thin-film solar cell. In the method according some embodiments, a first electrode layer is formed on a first substrate. A photoelectric conversion layer is formed on the first electrode layer. A second electrode layer is formed on the photoelectric conversion layer. The second electrode layer is disposed below a screen. Ink is applied on the screen. The screen comprises a screen frame, a screen cloth, and an emulsion layer. The screen cloth is knitted by warps and wefts and is arranged on the screen frame. Each of the warps and each of the wefts are respectively parallel with or perpendicular to the screen frame. Each of the warps is perpendicular to each of the wefts. The emulsion layer is disposed on the screen cloth and has a screen-printing pattern. A flood bar is moved along a first direction for covering the screen cloth with the ink. The ink is pressed downward by a scraper and the scraper is moved along a second direction for transferring at least a portion of the ink onto the second electrode layer through the screen-printing pattern, wherein a first angle between the scraper and each weft is in a range of 15° to 20° while the scraper is moved along the second direction.

In some embodiments of the method for manufacturing the thin-film solar cell, the reflecting layer on the second electrode layer is hardened by baking

In some embodiments of the method for manufacturing the thin-film solar cell, an adhesion layer is formed on the hardened reflecting layer and a second substrate is disposed on the adhesion layer, so as to encapsulate the first electrode layer, the photoelectric conversion layer, second electrode layer and the reflecting layer between the second substrate and the first substrate.

According to the above mentioned embodiments, the dimensional precision of the screen-printing layer and the reflecting layer is improved since each of the warps and each of the wefts are respectively parallel with or perpendicular to the screen frame. Furthermore, since the first angle formed between the scraper and each weft is in a range of 15° to 20° while the scraper is moved along the second direction, the screen cloth is not scratched easily by the scraper so that the service life of the screen is extended.

### BRIEF DESCRIPTION OF THE DRAWINGS

Unless otherwise specified, the same reference numbers are used through out the drawings to refer to the same or like elements in embodiments, and wherein:

FIG. 1A is a top view of a conventional screen;

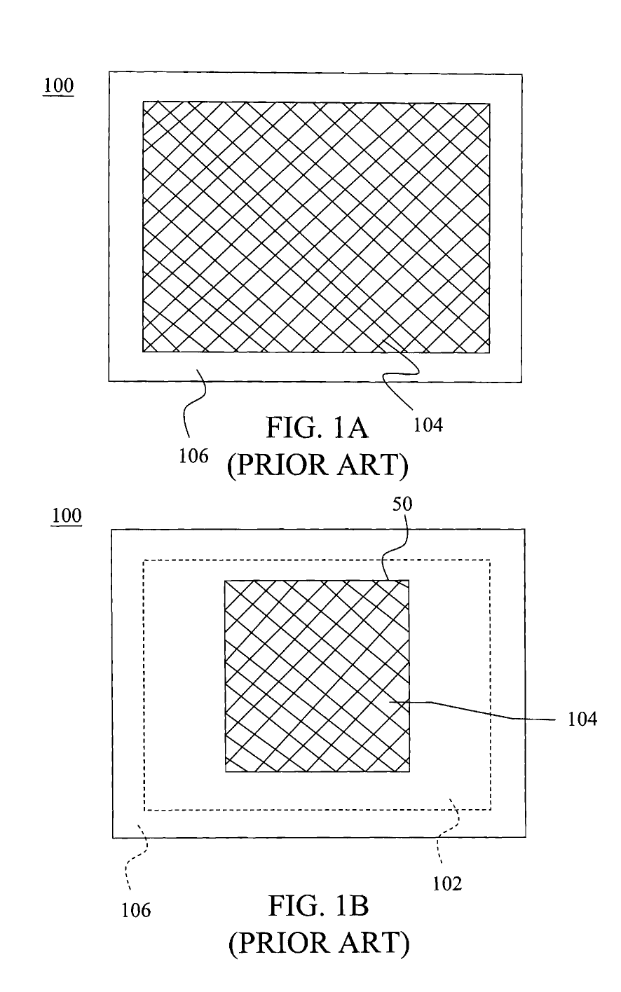

FIG. 1B is a bottom view of the conventional screen in FIG. 1A;

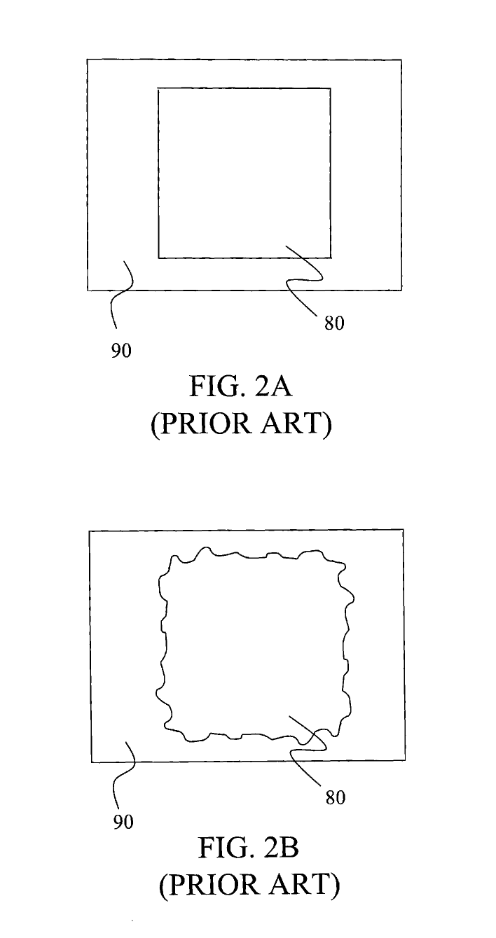

FIG. 2A is a top view of a ideal screen-printing layer generated by screen-printing;

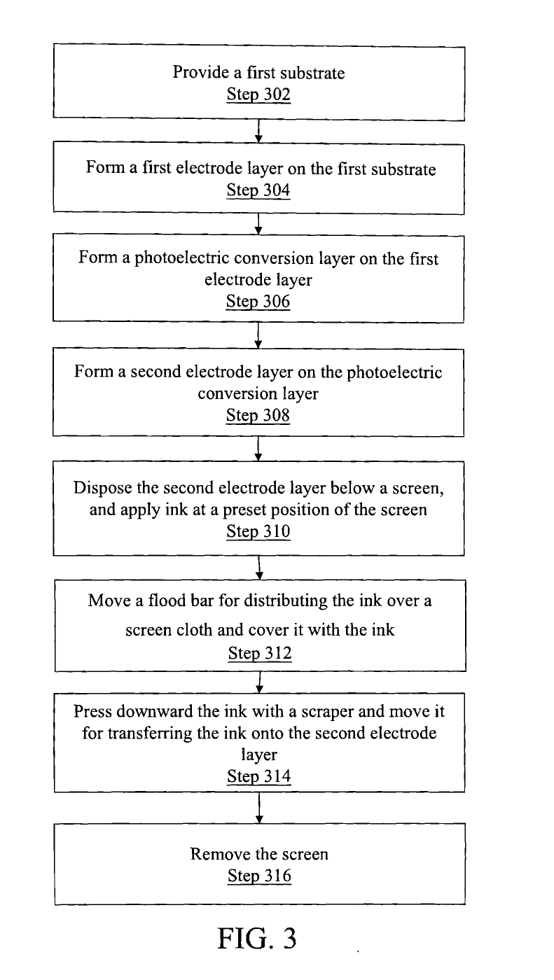

FIG. 2B is a top view of a screen-printing layer with serrate edges generated by conventional screen-printing process;

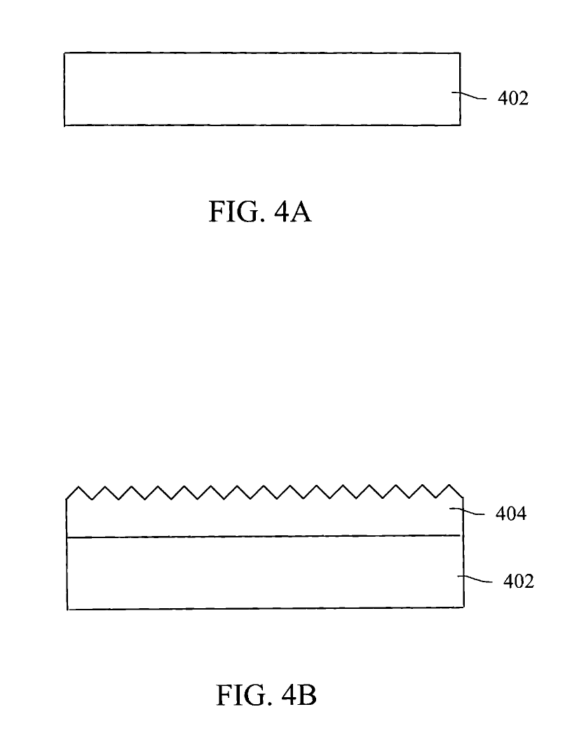

FIG. 3 is a flow chart of an embodiment of a method for manufacturing a thin-film solar cell;

FIGS. 4A to 4H are respectively cross sectional views of the intermediate structures formed by Steps 302 to 316 in FIG. 3;

FIG. 5 is a bottom view of the intermediate structure in FIG. 4E;

FIG. 6 is a top view of the intermediate structure in FIG. 4G;

FIG. 7 is a flow chart of another embodiment of the method for manufacturing the thin-film solar cell;

FIG. 8 is a flow chart of still another embodiment of the method for manufacturing the thin-film solar cell; and

FIG. 9 is a cross sectional view of the intermediate structure formed by Step 320 in FIG. 8.

### DETAILED DESCRIPTION

In the following detailed description, for purposes of explanation, numerous specific details are set forth in order to provide a thorough understanding of the detail embodiments. It will be apparent, however, that one or more embodiments may be practiced without these specific details. In other instances, well-known structures and devices are schematically shown in order to simplify the drawing.

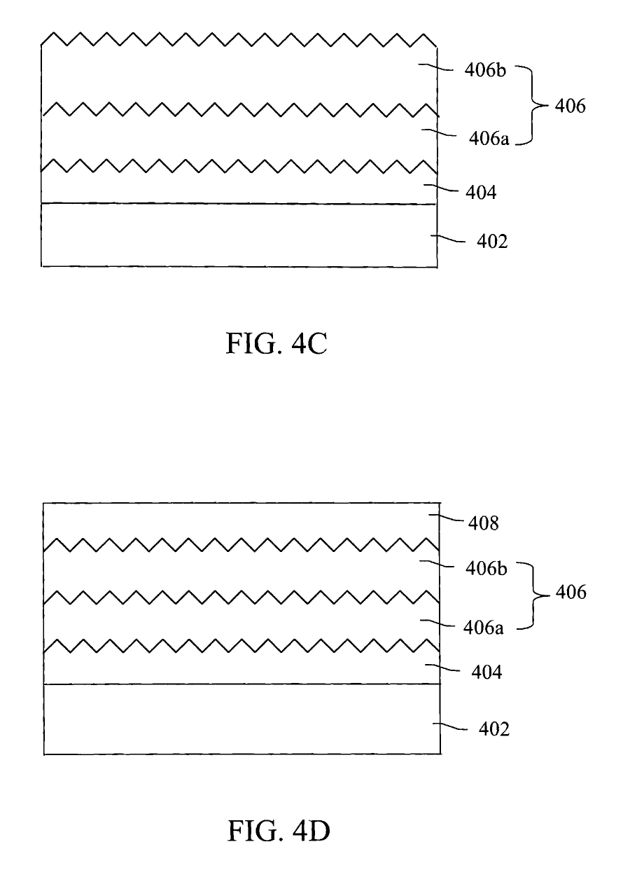

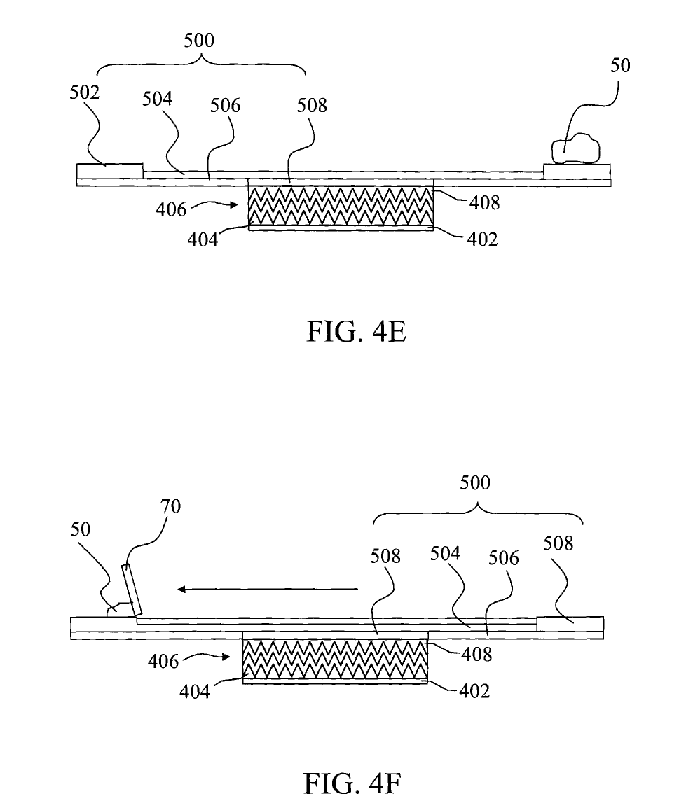

FIG. 3 is a flow chart of an embodiment of a method for manufacturing a thin-film solar cell according to the present invention. FIGS. 4A to 4H are cross sectional views of the intermediate structures formed by Steps 302 to 316 in FIG. 3, respectively. Referring to FIGS. 3 and 4A to 4H, the method for manufacturing the thin-film solar cell comprises the following steps.

In Step 302, a first substrate 402 is provided.

In Step 304, a first electrode layer 404 is formed on the first substrate 402.

In Step 306, a photoelectric conversion layer 406 is formed on the first electrode layer 404.

In Step 308, a second electrode layer 408 is formed on the photoelectric conversion layer 406.

In Step 310, the second electrode layer 408 is disposed below a screen 500, and ink 50 is applied at a preset position of the screen 500.

In Step 312, a flood bar 70 is moved along a first direction for distributing the ink 50 over a screen cloth 504 and covering the screen cloth 504 with the ink 50.

In Step 314, the ink 50 is pressed downward by a scraper 72 and the scraper 72 is moved along a second direction for transferring at least a portion of the ink 50 onto the second electrode layer 408 through the screen-printing pattern 508 for forming a reflecting layer 60, i.e. a screen printing layer. While the scraper 72 is moved along the second direction, a first angle θ₁ is formed between the scraper 72 and each weft 32, and the first angle θ₁ is in a range of 15° to 20°.

In Step 316, the screen 500 is removed.

In Step 302, the first substrate 402 may be, but not limited to, an anti-reflection glass substrate (as shown in FIG. 4A). In Step 304, the material of the first electrode layer 404 may be, but not limited to, transparent conducting oxides (TCO). In some embodiments, the TCO is indium tin oxide (ITO), indium sesquioxide (In₂O₃), tin dioxide (SnO₂), zinc oxide (ZnO), cadmium oxide (CdO), Al doped zinc oxide (AZO), or indium zinc oxide (IZO). The method for forming the first electrode layer 404 on the substrate 402 may be, but not limited to, electron beam evaporation, physical vapor deposition (PVD), or sputtering deposition, and may be adjusted according to characteristics of the material of the first electrode layer 404 (as shown in FIG. 4B).

In Step 306, the photoelectric conversion layer 406 may comprise a first conversion layer 406a and a second conversion layer 406b. The first conversion layer 406a may be an amorphous silicon (a-Si) photoelectric conversion layer, and may absorb short-wavelength having the wavelength in a range of about 400 nm to 700 nm. The second conversion layer 406b may be a microcrystalline silicon (μc-Si) photoelectric conversion layer, and may absorb long-wavelength light having the wavelength in a range of about 700 nm to 1100 nm. However, the wavelengths absorbed by the first conversion layer 406a and the second conversion layer 406b in this embodiment are not intended to limit the present invention, and may be adjusted as required. The first conversion layer 406a and the second conversion layer 406b may be respectively formed on the first electrode layer 404 and the first conversion layer 406a through, for example, but not limited to, a chemical vapor deposition (CVD) method. The CVD method may be, but not limited to, radio frequency plasma enhanced chemical vapor deposition (RF PECVD), very high frequency plasma enhanced chemical vapor deposition (VHF PECVD), or microwave plasma enhanced chemical vapor deposition (MW PECVD (as shown in FIG. 4C).

The second electrode layer 408 described in Step 308 may be, but not limited to, a transparent conductive film or a metal layer, and the material of the metal layer may be, but not limited to, silver or aluminum. The method for forming the second electrode layer 408 on the second conversion layer 406b may be, but not limited to, electron beam evaporation, PVD, or sputtering deposition method, and may be adjusted according to characteristics of the material of the second electrode layer 408 (as shown in FIG. 4D).

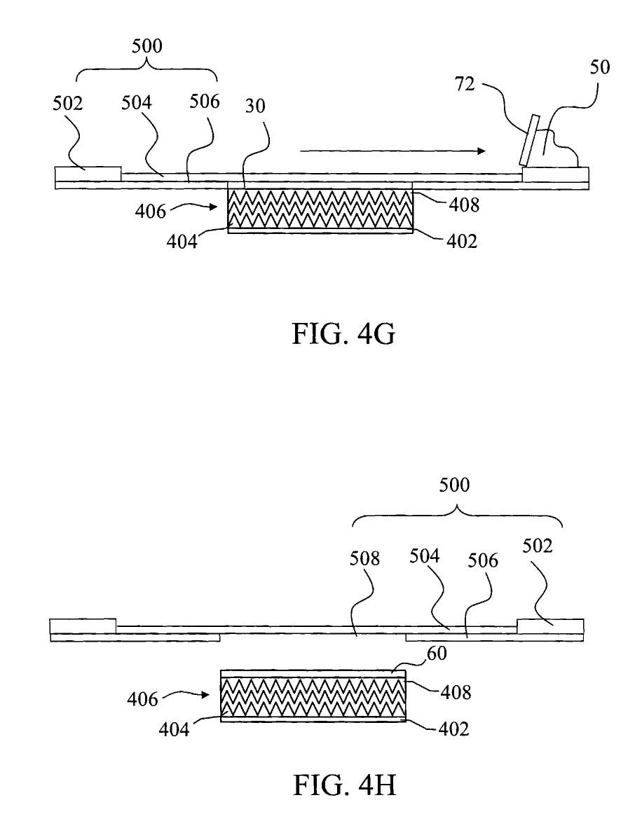

The screen 500 described in Step 310 comprises a screen frame 502, a screen cloth 504, and an emulsion layer 506. The screen cloth 504 is knitted by warps 30 and wefts 32 and is arranged on the screen frame 502. Each warp 30 and each weft 32 are respectively parallel with or perpendicular to the screen frame 502, and each warp 30 is perpendicular to each weft 32. The warps 30 are mutually parallel, and the wefts 32 are also mutually parallel. The materials of the warp 30 and the weft 32 may be, but not limited to, nylon, polyester, or metal. The emulsion layer 506 is disposed on the screen cloth 504 and has a screen-printing pattern. In this embodiment, the screen-printing pattern may be, but not limited to, a rectangular opening area 508 (referring to FIGS. 4E and 5, where FIG. 5 is a bottom view of an embodiment of the screen shown in FIG. 4E). Furthermore, the ink 50 described in Step 310 is used to form the reflecting layer 60 in step 314. The material of the reflecting layer 60 may be, but not limited to, a mixture of hardener and titanium dioxide, and may be adjusted according to different requirements.

The first direction described in Step 312 is a moving direction of the flood bar 70 for covering the screen cloth 504 with the ink 59. And in this embodiment, the first direction is indicated by the arrow in FIG. 4F.

The second direction described in Step 314 is a moving direction of the scraper 72 for transferring at least a portion of the ink 50 on the second electrode layer 408 through the screen-printing pattern (the rectangular opening area 508), thereby the reflecting layer 60 is formed. Accordingly, the shape of the reflecting layer 60 is corresponding to the contour of the screen-printing pattern (the rectangular opening area 508).

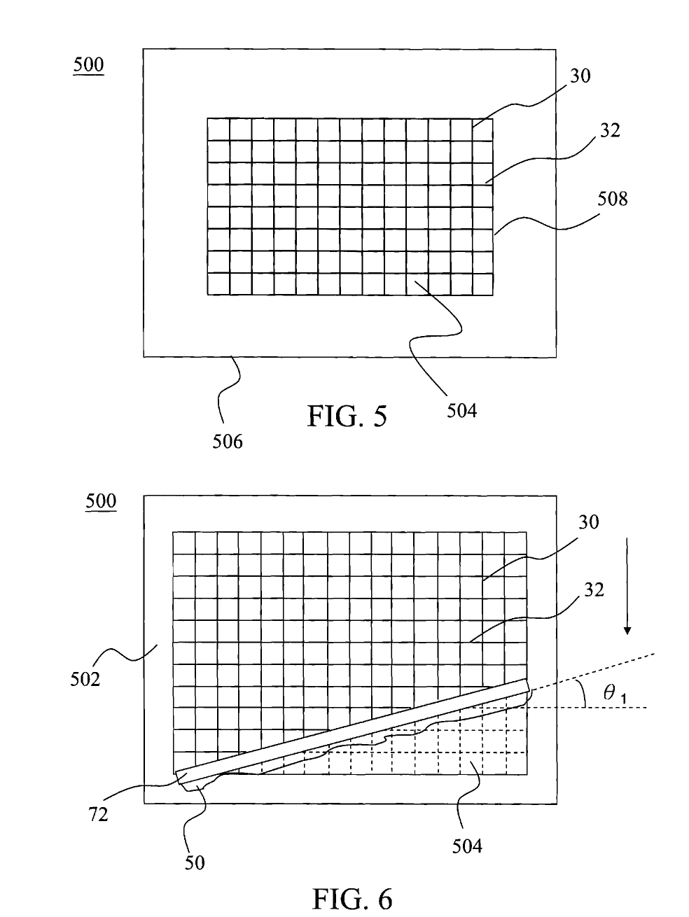

In this embodiment, the second direction is indicated by the arrow in FIG. 4G. While the scraper 72 is moved along the second direction, a first angle θ₁ is formed between the scraper 72 and each weft 32, and the first angle θ₁ is in a range of 15° to 20°, so as to prevent the scraper 72 from scratching the screen cloth 504 (referring to FIG. 6, which is a top view of FIG. 4G). Specifically, the first angle θ₁is formed between the surface of the scraper 72 contacting the ink 50 and each weft 32.

The reflecting layer 60 described in Step 316 is formed by the ink 50 distributed corresponding to the contour of the rectangular opening area 508.

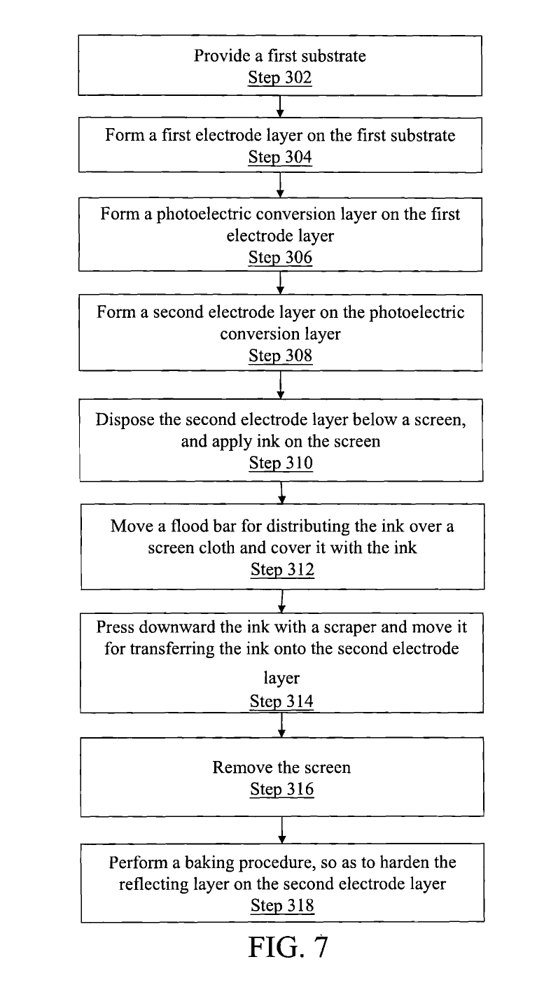

FIG. 7 is a flow chart of another embodiment of the method for manufacturing the thin-film solar cell. Referring to FIG. 7, in this embodiment, in addition to Steps 302 to 316, the method for manufacturing the thin-film solar cell further comprises the following step.

In Step 318, the reflecting layer 60 on the second electrode layer 408 is hardened by a baking procedure.

Since the ink 50 is in a liquid state before baking, the baking procedure is required in order to harden the ink 50 for forming the reflecting layer 60 on the second electrode layer 408.

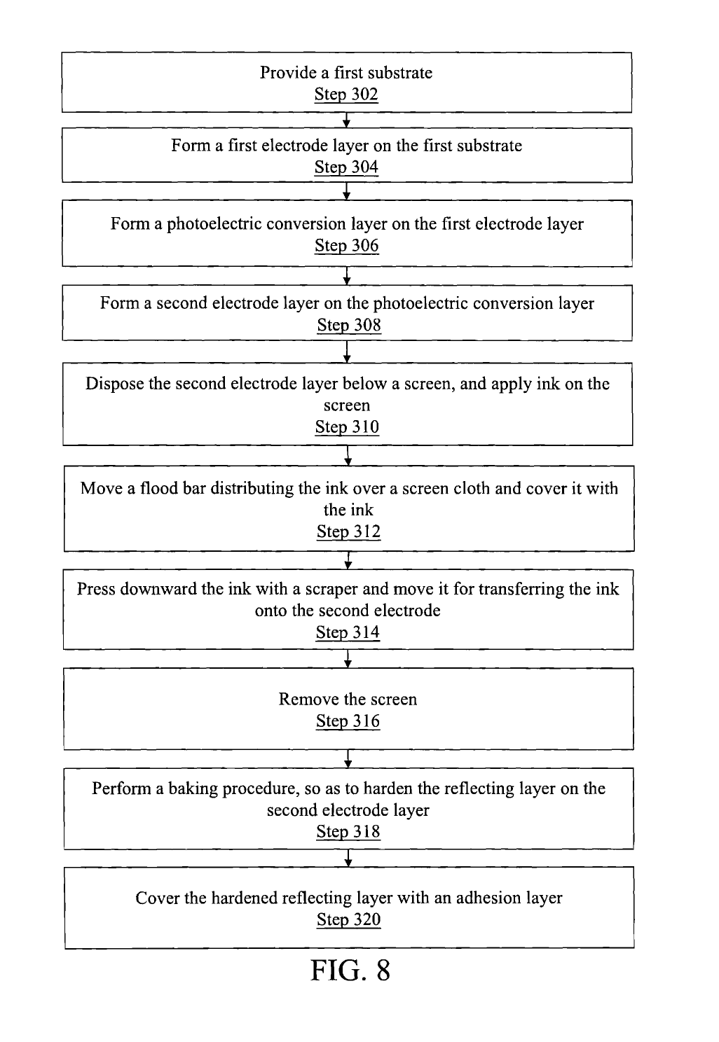

FIG. 8 is a flow chart of still another embodiment of the method for manufacturing the thin-film solar cell. Referring to FIG. 8, in this embodiment, in addition to Steps 302 to 318, the method for manufacturing the thin-film solar cell further comprises the following step.

In Step 320, the hardened reflecting layer 60 is covered with an adhesion layer 410 and a second substrate 412 is disposed on the adhesion layer 410, so as to encapsulate the first electrode layer 404, photoelectric conversion layer 46, and the second electrode layer 408 between the second substrate 412 and the first substrate 402.

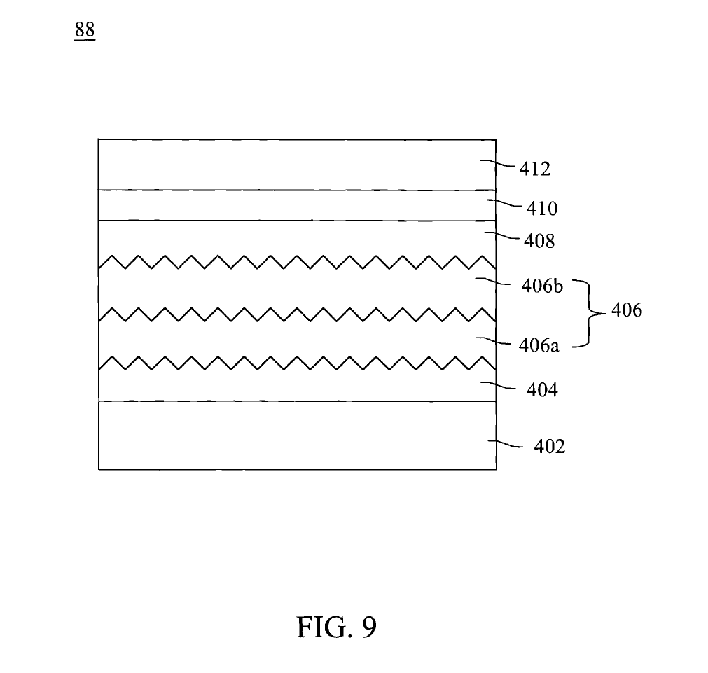

According to Step 320 (referring to FIG. 9, which is a view of the intermediate structure made by Step 320 in FIG. 8), the first electrode layer 404, photoelectric conversion layer 46, and the second electrode layer 408 through the adhesion layer 410 are encapsulated by the second substrate 412 and the first substrate 402 to prevent water vapor from permeating in the thin-film solar cell 88, so that the problems of current leakage or deterioration of the film layer of the solar cell 88 is avoided.

According to the above mentioned embodiments, the dimensional precision of the reflecting layer is improved since each warp and each weft are respectively parallel with or perpendicular to the screen frame. Furthermore, since the first angle formed between the scraper and each weft is in a range of 15° to 20° while the scraper is moved along the second direction, the screen cloth is not scratched easily by the scraper so that the service life of the screen is extended.

What is claimed is:

1. A screen-printing method, applicable to forming a screen-printing layer on an object, the method comprising:
disposing the object below a screen and applying an ink on the screen, wherein the screen comprises a screen frame, a screen cloth, and an emulsion layer, the screen cloth is knitted by a plurality of warps and a plurality of wefts and is arranged on the screen frame, each of the warps and each of the wefts are respectively parallel with or perpendicular to the screen frame, each of the warps is perpendicular to each of the wefts, and the emulsion layer is disposed on the screen cloth and has a screen-printing pattern;
moving a flood bar along a first direction for covering the screen cloth with the ink; and
pressing the ink downward by a scraper and moving the scraper along a second direction for transferring at least a portion of the ink onto the object through the screen-printing pattern, wherein a first angle between the scraper and the warps is in a range of 15° to 20° while the scraper is moved along the second direction.

2. A method for manufacturing a thin-film solar cell, comprising:
forming a first electrode layer on a first substrate;
forming a photoelectric conversion layer on the first electrode layer;
forming a second electrode layer on the photoelectric conversion layer;
disposing the second electrode layer below a screen, and applying an ink on the screen, wherein the screen comprises a screen frame, a screen cloth, and an emulsion layer, the screen cloth is knitted by a plurality of warps and a plurality of wefts and is arranged on the screen frame, each of the warps and each of the wefts are respectively parallel with or perpendicular to the screen frame, each of the warps is perpendicular to each of the wefts, and the emulsion layer is disposed on the screen cloth and has a screen-printing pattern;
moving a flood bar along a first direction for covering the screen cloth with the ink; and
pressing the ink downward by a scraper and moving the scraper along a second direction for transferring at least a portion of the ink onto the second electrode layer through the screen-printing pattern, wherein a first angle between the scraper and the wefts is in a range of 15° to 20° while the scraper is moved along the second direction.

3. The method for manufacturing the thin-film solar cell according to claim 2, further comprising hardening the reflecting layer on the second electrode layer by baking.

4. The method for manufacturing the thin-film solar cell according to claim 3, further comprising forming an adhesion layer on the hardened reflecting layer and disposing a second substrate on the adhesion layer for encapsulating the first electrode layer, the photoelectric conversion layer, second electrode layer and the reflecting layer between the second substrate and the first substrate.
